(19) United States
(12) Patent Application Publication
(10) Pub. No.: US 2025/0113672 A1
(43) Pub. Date: Apr. 3, 2025

(54) SUBSTRATE, LIGHT-EMITTING MODULE, AND PREPARATION METHOD THEREOF

(71) Applicant: FOSHAN NATIONSTAR OPTOELECTRONICS CO., LTD., Guangdong (CN)

(72) Inventors: Guanyu WANG, Foshan (CN); Mingwen LAN, Foshan (CN); Nianbin CHENG, Foshan (CN); Yongzhao OU, Foshan (CN); Lu YANG, Foshan (CN); Yuanyuan DONG, Foshan (CN)

(21) Appl. No.: 18/774,350

(22) Filed: Jul. 16, 2024

(30) Foreign Application Priority Data
Sep. 28, 2023 (CN) 2023112778323
Sep. 28, 2023 (CN) 2023226622621

(51) Int. Cl. H01L 33/40; H01L 33/00; H01L 33/56

(52) U.S. Cl. CPC H10H 20/832; H10H 20/01; H10H 20/854

(57) ABSTRACT

A substrate includes a substrate body and a top copper layer disposed on the substrate body. Multiple insulated channels are disposed on the top copper layer. The top copper layer forms a top circuit structure based on the multiple insulated channels. A light-emitting element installation region is disposed on the top layer circuit structure. The top copper layer in the light-emitting element installation region protrudes upward to form at least one copper layer boss. Multiple light-emitting element welding positions are disposed in the light-emitting element installation region. A light-emitting element welding position is disposed on any copper layer boss. The copper layer boss is configured to adjust the height of the light emission surface of a light-emitting element disposed in the light-emitting element installation region.

### CROSS-REFERENCE TO RELATED APPLICATION(S)

This application claims the priority of a Chinese Patent Application No. 202322662262.1, filed on Sep. 28, 2023, and the priority of a Chinese Patent Application No. 202311277832.3, filed on Sep. 28, 2023, the disclosure of which are incorporated herein by reference in their entireties.

### TECHNICAL FIELD

The present application mainly relates to the technical field of light-emitting modules, in particular, a substrate, a light-emitting module, and a preparation method thereof.

### BACKGROUND

In the current process of encapsulating light-emitting modules, light-emitting elements are installed in light-emitting element installation regions of substrates. To ensure that the light-emitting modules have a good light-emitting effect, the light-emitting surfaces of the light-emitting elements need to maintain a preset distance from the light outlets. Since the size specifications of the light-emitting elements integrated on the substrates are not completely consistent, the installation height of some light-emitting elements needs to be adjusted to meet the light quality requirements of the light-emitting modules.

In the existing encapsulation method, a pad is disposed at the installation position of a light-emitting element to adjust the installation height of the light-emitting element. However, currently, the pad needs to be fastened to a circuit layer of the substrate through bottom solder welding and is connected to the light-emitting element through the top solder, resulting in a decreasing of thermal conductivity between the light-emitting element and the substrate, thereby affecting the heat dissipation performance of the light-emitting element.

### SUMMARY

The present application provides a substrate, a light-emitting module, and a preparation method thereof.

The present application provides a substrate. The substrate includes a substrate body and a top copper layer disposed on the substrate body. A plurality of insulated channels are disposed on the top copper layer. The top copper layer forms a top circuit structure based on the plurality of insulated channels. A light-emitting element installation region is disposed on the top layer circuit structure.

The top copper layer in the light-emitting element installation region protrudes upward to form at least one copper layer boss.

A plurality of light-emitting element welding positions are disposed in the light-emitting element installation region. A light-emitting element welding position is disposed on any copper layer boss. The copper layer boss is configured to adjust the height of the light emission surface of a light-emitting element disposed in the light-emitting element installation region so that the height of the light emission surface of any light-emitting element disposed in the light-emitting element installation region is on the same horizontal plane.

In some embodiments, the area of the top surface of the copper layer boss is larger than the area of the light-emitting element welding position.

In some embodiments, the difference between the length of the contour edge of the top surface of the copper layer boss and the length of the contour edge of the light-emitting element welding position is d, and the value range of the difference d is as follows: 4 μm≤d≤6 μm.

In some embodiments, a stepped structure is formed on the circumferential sidewall of the copper layer boss, or the circumferential sidewall of the copper layer boss is a smooth surface structure.

In some embodiments, the material of the substrate body is ceramic.

In some embodiments, the top copper layer and the copper layer boss are an integrally formed structure.

In some embodiments, a plurality of barrier layers are disposed in the plurality of insulated channels, and the plurality of barrier layers are disposed at intersections between the contour line of the light-emitting element installation region and the insulated channels.

In some embodiments, the top surface of a barrier layer is flush with the top surface of the top copper layer.

In some embodiments, the width of a barrier layer is the same as the width of an insulated channel.

In some embodiments, a barrier layer is connected to the contour line of the light-emitting element installation, or a barrier layer intersects with the contour line of the light-emitting element installation region.

In some embodiments, the barrier layer is connected to the contour line of the light-emitting element installation region, one end surface of the barrier layer is an arc surface.

In some embodiments, the top arc of the arc surface of the one end surface of the barrier layer is the same as the arc of the contour line of the light-emitting element installation region.

In some embodiments, the material of a barrier layer is ink, silicone, or epoxy resin.

In some embodiments, the barrier layer is a transparent barrier layer or a white barrier layer.

In some embodiments, the color of the barrier layer is the same as the light-emitting color of the light-emitting element in the light-emitting element installation region.

The present application also provides a light-emitting module. The light-emitting module includes a substrate, a plastic encapsulation layer disposed on the substrate, and a light-emitting element disposed in a light-emitting element installation region of the substrate.

A light-emitting cavity channel is disposed in the plastic encapsulation layer. The light-emitting element is disposed in the light-emitting cavity channel.

In some embodiments, the top port of the light-emitting cavity channel is set as a light outlet.

The distance between the light emission surface of the light-emitting element on the substrate and the light outlet is H1, the distance between the top surface of a top copper layer on the substrate and the light outlet is H2, the thickness of the light-emitting element is h1, and the thickness of a copper layer boss is h2, where the constraint relationship between H1, H2, h1, and h2 is as follows: h1+h2=H2−H1.

The present application also provides a method for preparing a substrate. The preparation method is used to prepare the substrate and includes the steps below.

A top copper layer is formed on the top surface of a substrate body using a copper coating process.

Deposition is performed on the top copper layer to form a superimposed copper layer, and the superimposed copper layer is marked to form a reserved region.

The superimposed copper layer outside the reserved region on the superimposed copper layer is etched and removed to prepare a copper layer boss.

In some embodiments, forming the top copper layer on the top surface of the substrate body using the copper coating process includes the steps below.

Copper is coated on the substrate body using a direct bond copper (DBC) process, the top copper layer is formed on the top surface of the substrate body, and a bottom copper layer is formed on the bottom surface of the substrate body.

In some embodiments, performing deposition on the top copper layer to form the superimposed copper layer and marking on the superimposed copper layer to form the reserved region include the steps below.

Copper metal is deposited on the top copper layer by metal sputtering so that the superimposed copper layer of a certain thickness is formed on the top surface of the top copper layer, and by laser etching, the surface of the superimposed copper layer is marked to form the reserved region.

In some embodiments, etching and removing the superimposed copper layer outside the reserved region on the superimposed copper layer to prepare the copper layer boss includes the steps below.

A laser routing start point, a routing end point, and a routing path of a laser etching device are set, and by laser etching, the superimposed copper layer outside the reserved region on the superimposed copper layer is etched and removed.

The present application also provides a method for preparing a substrate. The preparation method is used to prepare the substrate and includes the steps below.

A top copper layer is formed on the top surface of a substrate body using a copper coating process.

A mask with a preset slot is prepared on the top copper layer, where the preset slot corresponds to a light-emitting element installation region of the top copper layer.

Copper ions are deposited on the slot to form a deposited copper layer, and a copper layer boss is formed based on a plurality of depositions.

The mask is etched and removed to obtain a substrate with the copper layer boss.

In some embodiments, preparing the mask with the preset slot on the top copper layer and the preset slot corresponding to the light-emitting element installation region of the top copper layer include the steps below.

A photosensitive film is attached to the top copper layer, and the photosensitive film is exposed.

A developer is coated on the photosensitive film, and based on the developer, the photosensitive film is etched to form the slot.

The substrate body is rinsed and dried.

In some embodiments, attaching the photosensitive film to the top copper layer and exposing the photosensitive film include the steps below.

The photosensitive film is attached to the top copper layer, the position of a reserved region is marked on the photosensitive film according to the encapsulation size requirement of the substrate and the installation requirement of the light-emitting element, and the reserved region of the photosensitive film is exposed using a lighting device.

In some embodiments, coating the developer on the photosensitive film and etching the photosensitive film based on the developer to form the slot include the steps below.

The developer is stored in a spraying device, and the nozzle of the spraying device is driven to rotate and spray the developer above the photosensitive film so that the developer evenly covers the surface of the photosensitive film.

In some embodiments, etching and removing the mask to obtain the substrate with the copper layer boss includes the steps below.

The mask is exposed, and the exposed mask is soaked in a developer so that the mask can be completely dissolved in the developer, thereby etching and stripping the mask to obtain the substrate with the copper layer boss.

### BRIEF DESCRIPTION OF DRAWINGS

FIG. 1 is a diagram illustrating the structure of a substrate according to some embodiments of the present application.

FIG. 2 is a top view of a copper layer boss according to some embodiments of the present application.

FIG. 3 is a diagram illustrating the structure of a copper layer boss according to some embodiments of the present application.

FIG. 4 is a diagram illustrating another state of the copper layer boss structure according to some embodiments of the present application.

FIG. 5 is a flowchart of a method for preparing a substrate according to some embodiments of the present application.

FIG. 6 is a flowchart of a method for preparing a substrate according to some embodiments of the present application.

FIG. 7 is a flowchart of a method for preparing a mask according to some embodiments of the present application.

FIG. 8 is a diagram illustrating the structure of a substrate according to some embodiments of the present application.

FIG. 9 is a diagram illustrating the structure of a substrate according to some embodiments of the present application.

FIG. 10 is a diagram illustrating the structure of a substrate according to some embodiments of the present application.

FIG. 11 is a sectional view illustrating the structure of a light-emitting module according to some embodiments of the present application.

### DETAILED DESCRIPTION

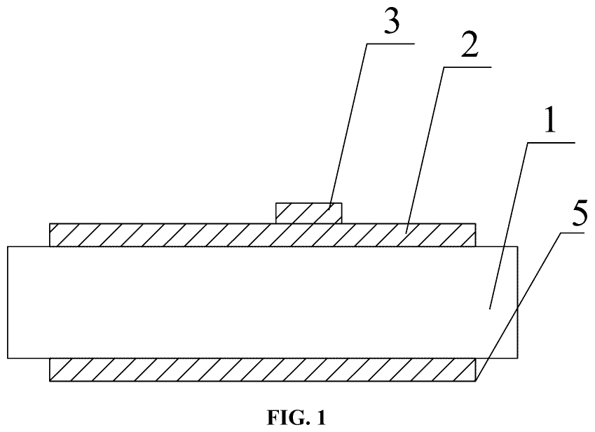

FIG. 1 is a diagram illustrating the structure of a substrate according to some embodiments of the present application. The substrate includes a substrate body 1 and a top copper layer 2 disposed on the substrate body 1. Multiple insulated channels 12 are disposed on the top copper layer 2. The top copper layer 2 forms a top circuit structure based on the multiple insulated channels 12. A light-emitting element installation region 13 is disposed on the top layer circuit structure. The light-emitting element installation region 13 is used to install a light-emitting element 6 (as shown in FIG. 11). The top circuit structure may also be integrated with a variety of other electronic components, such as a driver IC and other passive components, including resistors, capacitors, inductors, and Zener diodes to achieve the light-emitting drive of the light-emitting element 6.

In some embodiments, the light-emitting element 6 may be a light-emitting chip, a light-emitting component, or a Zener diode.

In some embodiments, the light-emitting chip may be a blue chip, a green chip, a red chip, an ultraviolet chip, or an infrared chip; the light-emitting component may be a single-color chip encapsulation component, such as a blue chip encapsulation component with fluorescent adhesive; the light-emitting component may also be a multi-color chip encapsulation component, such as an RGB chip encapsulation component with a transparent adhesive layer.

The light-emitting element 6 is electrically connected to the light-emitting element installation region 13 so that the light-emitting element 6 is connected to the top layer circuit structure. Thus, the substrate drives the light-emitting element 6 to work.

Illustratively, the substrate body 1 may be a ceramic substrate. A bottom copper layer 5 is disposed at the bottom of the substrate body 1 and is used to assist heat dissipation. The heat generated by the light-emitting element 6 and other electronic components on the top circuit structure during operation can be conducted outward through the ceramic substrate and the bottom copper layer 5, thereby improving the heat dissipation performance of the substrate.

Illustratively, the top copper layer 2 in the light-emitting element installation region 13 protrudes upward to form at least one copper layer boss 3 for carrying the light-emitting element 6. Multiple light-emitting element welding positions 4 are disposed in the light-emitting element installation region 13. At least one light-emitting element welding position 4 is correspondingly arranged on any copper layer boss 3. The copper layer boss 3 is configured to adjust the height of the light emission surface of the light-emitting element 6 disposed in the light-emitting element installation region 13 so that the height of the light emission surface of the light-emitting element 6 is on the same horizontal plane, that is, the light emission surfaces of some light-emitting elements 6 are kept at the same height as the light emission surfaces of other light-emitting elements 6 based on the copper layer bosses 3. For example, after the at least one copper layer boss 3 is provided, it is ensured that for two chips of different heights, the light emission surface is at the same horizontal plane, regardless of which chip is used.

In some embodiments, the at least one copper layer boss 3 is disposed in the light-emitting element installation region 13 so that the height of the light emission surface of the light-emitting element 6 disposed in the light-emitting element installation region 13 is on the same horizontal plane, thereby ensuring the light-emitting effect of the light-emitting element 6 on the substrate.

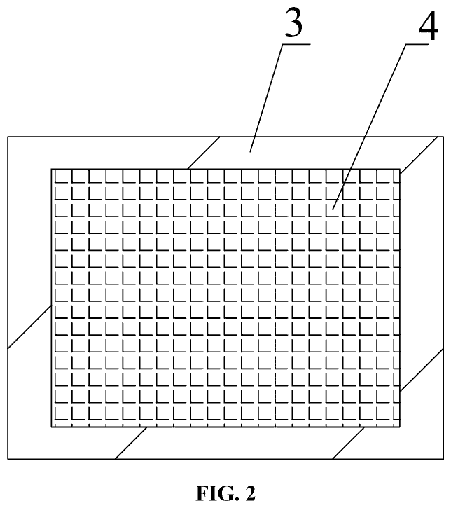

Illustratively, FIG. 2 is a top view of a copper layer boss 3 according to some embodiments of the present application. The area of the top surface of the copper layer boss 3 is larger than the area of the light-emitting element welding position 4. The difference between the length of the contour edge of the top surface of the copper layer boss 3 and the length of the contour edge of the light-emitting element welding position 4 is d, and the value range of the difference d is as follows: 4 μm≤d≤6 μm. In this manner, when the light-emitting element 6 is welded to the copper layer boss 3, sufficient offset space can be reserved on the copper layer boss 3 to prevent the light-emitting element 6 from being offset outside the copper layer boss 3 during installation, thereby ensuring the stability and reliability of the electrical connection between the light-emitting element 6 and the copper layer boss 3.

In some embodiments, the shape of the top surface of the copper layer boss 3 may be a polygon, for example, a square, a rectangle, or an irregular shape. The shape of the top surface of the copper layer boss 3 may also be circular, for example, a circle, an ellipse, or a semicircle. The shape of the copper layer boss 3 may be adjusted according to the requirement for installing and welding the light-emitting element 6 to ensure the installation reliability of the light-emitting element 6 on the substrate.

Illustratively, after the substrate is encapsulated, the distance between the light emission surface of the light-emitting element 6 on the substrate and the light outlet is H1, the distance between the top surface of the top copper layer 2 on the substrate and the light outlet is H2, the thickness of the light-emitting element 6 is h1, and the thickness of the copper layer boss 3 is h2, where the constraint relationship between H1, H2, h1, and h2 is as follows: h1+h2=H2−H1. H1 is set according to the actual encapsulation specification of the light-emitting element 6. The thickness h2 of the copper layer boss 3 can be calculated and determined by the thickness hl of the light-emitting element 6 and the distance H2 between the top surface of the top copper layer 2 on the substrate and the light outlet.

Illustratively, FIG. 3 is a diagram illustrating the structure of a copper layer boss 3 according to some embodiments of the present application. A stepped structure may be formed on the circumferential sidewall of the copper layer boss 3. The stepped structure can improve the adhesion ability of the circumferential sidewall of the copper layer boss 3 to the solder paste. Based on this structure, when the light-emitting element 6 is welded, the solder paste flows around the copper layer boss 3 and climbs along the circumferential outer wall of the copper layer boss 3. Based on the stepped structure on the circumferential sidewall, the solder paste can adhere to the circumferential sidewall.

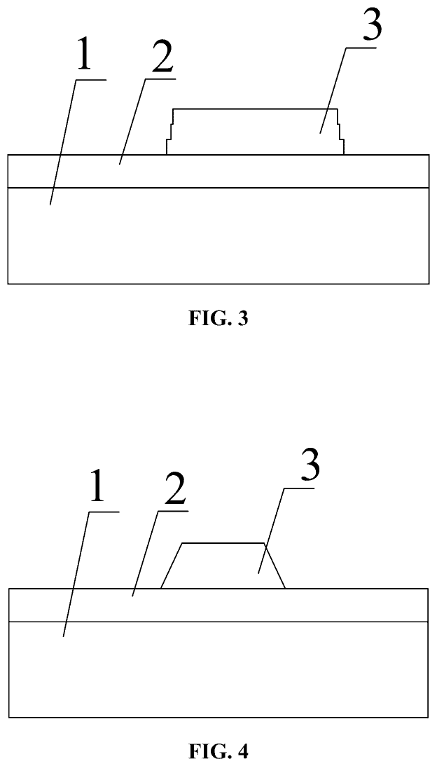

Illustratively, FIG. 4 is a diagram illustrating another state of the copper layer boss 3 structure according to some embodiments of the present application. The circumferential sidewall of the copper layer boss 3 may be a smooth surface structure, and based on the ductility of copper metal, the copper layer boss 3 is formed into a cone-shaped structure with the wire diameter gradually decreasing from bottom to top. In this manner, the structure of the copper layer boss 3 is stable and has good bearing capacity.

In some embodiments, a copper layer boss 3 is disposed on the substrate in the light-emitting element installation region 13. The light-emitting element is fastened to the copper layer boss 3. Thus, it can be ensured that the distance between the light emission surface of the light-emitting element 6 and the light outlet meets the light emission requirement of the light-emitting module and that the light-emitting element 6 has a good light emission angle.

In some embodiments, the copper layer boss 3 and the top copper layer 2 are an integrally formed structure. The light-emitting element 6 is disposed on the copper layer boss 3 so that the reliability of heat conduction of the light-emitting element 6 during operation can be ensured, and the heat dissipation performance of the substrate can be improved.

In some embodiments of present application, the copper layer boss is disposed on the top copper layer of the substrate, and the installation height of the light-emitting element is adjusted based on the copper layer boss so that the light-emitting element meets the light-emitting requirements. The copper layer boss and the top copper layer are an integrated structure, which can ensure that the light-emitting element has good heat dissipation performance.

Some embodiments of the present application provide a light-emitting module. The light-emitting module includes a substrate, a plastic encapsulation layer 7 (as shown in FIG. 11) disposed on the substrate, and a light-emitting element 6 (as shown in FIG. 11) disposed in a light-emitting element installation region 13 of the substrate.

A light-emitting cavity channel 71 is disposed in the plastic encapsulation layer 7. The light-emitting element 6 is disposed in the light-emitting cavity channel 71.

The top port of the light-emitting cavity channel 71 is set as a light outlet.

The distance between the light emission surface of the light-emitting element 6 on the substrate and the light outlet is H1, the distance between the top surface of the top copper layer 2 on the substrate and the light outlet is H2, the thickness of the light-emitting element 6 is h1, and the thickness of a copper layer boss 3 is h2, where the constraint relationship between H1, H2, h1, and h2 is as follows: h1+h2=H2−H1. By the provision of a copper layer boss 3 on the top copper layer 2 of the substrate, the light emission surface of the light-emitting element 6 of the substrate can be adjusted to be on the same horizontal plane based on the copper layer boss 3, thereby improving the light-emitting effect of the light-emitting module.

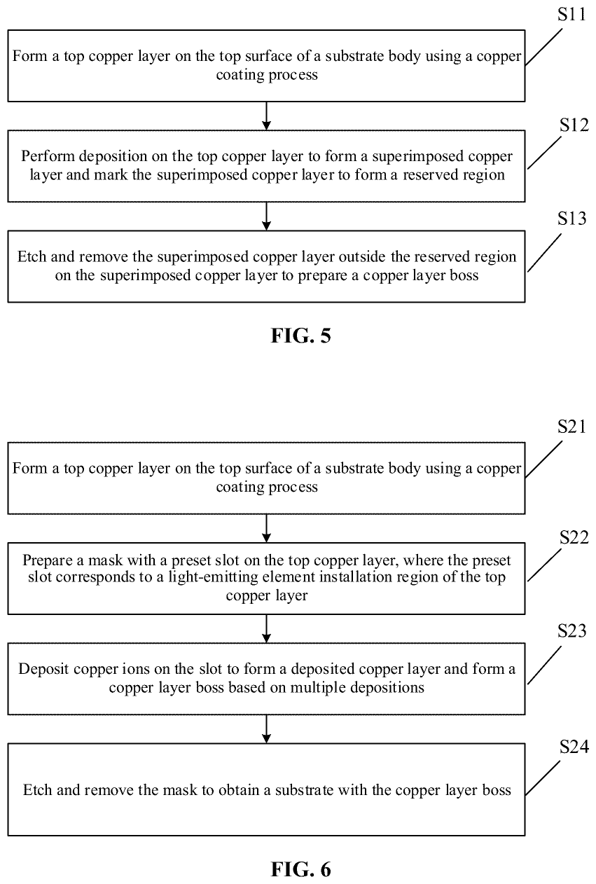

FIG. 5 is a flowchart of a method for preparing a substrate according to some embodiments of the present application. The preparation method includes the steps below.

In S11, a top copper layer 2 is formed on the top surface of a substrate body 1 using a copper coating process.

Illustratively, copper is coated on the substrate body 1 using the DBC process. Direct Bond Copper (DBC) is a ceramic surface metallization technology developed based on alumina ceramic substrates. By the attachment of copper foil to the substrate body 1, a copper layer is formed on the surface of the substrate body 1.

Illustratively, a copper foil with a preset thickness is provided, and the copper foil is placed in the air for pre-oxidation so that a certain thickness of copper oxide is formed on the surface of the copper foil.

Illustratively, a copper foil with a thickness of 0.1 mm or more is placed in the air for oxidation so that an oxide layer, that is, copper oxide, is generated on the surface of the copper foil. The thickness of the oxide layer accounts for about 20% of the thickness of the copper foil so that the copper foil contains a sufficient amount of oxygen atoms.

In some embodiments, the pre-oxidation operation of the copper foil may also include the following: by the placement of the copper foil in a nitrogen environment containing 1% oxygen for weak oxidation, a certain thickness of cuprous oxide is generated on the copper foil, thereby having a certain amount of oxygen atoms combined with the copper foil.

The pre-oxidized copper foil is attached to the top surface of the substrate body 1, and the copper foil is fixed to the substrate body 1 by high-temperature sintering.

Illustratively, the pre-oxidized copper foil is covered on the top surface of the substrate body 1, and the substrate body 1 and the copper foil are placed at a preset temperature and heated for a preset time so that a Cu—Cu₂O eutectic liquid is formed between the substrate body 1 and the copper foil, that is, a eutectic liquid of copper and cuprous oxide is formed. In this manner, the copper foil has good wettability to the substrate body 1, and the copper foil can be fixed on the substrate body 1 by generating a CuAlO₂ layer.

In some embodiments, the preset temperature is T, and the value range of T is as follows: 1065° C.≤T≤1083° C.; the preset time is t, and the value range of t is as follows: 10 min≤t≤15 min.

Illustratively, the copper foil and the substrate body 1 are cooled so that the copper foil is bonded and fixed to the substrate body 1, thereby preparing the top copper layer 2 on the top surface of the substrate body 1.

In some embodiments, the bottom copper layer 5 on the bottom surface of the substrate body 1 is formed based on the same process as the process of forming the top copper layer 2, and the top copper layer 2 and the bottom copper layer 5 may be simultaneously prepared, thereby improving the preparation and processing efficiency of the top copper layer 2 of the substrate body 1.

In S12, deposition is performed on the top copper layer 2 to form a superimposed copper layer, and the superimposed copper layer is marked to form a reserved region.

Illustratively, copper metal is deposited on the top copper layer 2 by metal sputtering so that a superimposed copper layer of a certain thickness is formed on the top surface of the top copper layer 2, and by laser etching, the surface of the superimposed copper layer is marked to form a reserved region. The position of a corresponding light-emitting element installation region 13 is determined on the superimposed copper layer according to the circuit structure layout design of the substrate. The region in which the copper layer boss 3 is located is marked in the light-emitting element installation region 13 according to the requirements of the installation position of the light-emitting element 6 of the substrate, and the laser is controlled to etch along a route of the contour of the region in which the copper layer boss 3 is located so that the reserved region is formed.

In some embodiments, the circuit structure design layout of the substrate is input to the control system of a laser etching device, and the circuit structure design layout is adjusted in size and then projected onto the surface of the superimposed copper layer to obtain the position of the light-emitting element installation region 13 on the substrate corresponding to the superimposed copper layer.

In some embodiments, the thickness of the superimposed copper layer may be determined according to the specifications of the light-emitting element 6 and the light-emitting module encapsulated by the substrate to ensure that the height of the copper layer boss 3 after molding meets the encapsulation requirements of the light-emitting element 6.

In some embodiments, the area of the reserved region is slightly larger than the area of the orthographic projection of the light-emitting element 6 to facilitate the welding and fixing of the light-emitting element 6.

In S13, the superimposed copper layer outside the reserved region on the superimposed copper layer is etched and removed to prepare a copper layer boss 3.

Illustratively, the superimposed copper layer outside the reserved region on the superimposed copper layer is etched and removed by laser etching, and a laser routing start point, a routing end point, and a routing path of a laser etching device are set so that the laser etching device performs routing etching on the superimposed copper layer. By the configuration of the laser beam power of the laser etching device and the routing rate of the laser beam, the etching depth of the superimposed copper layer by the laser etching device can be controlled.

In some embodiments, the laser beam frequency emitted by the laser etching device is set to 50 kHz, and the routing rate is set to 800 mm/s so that for each wiring, the laser etching device can etch and remove the superimposed copper layer of a preset depth. By routing back multiple times, the portion outside the reserved region of the superimposed copper layer is completely removed, thereby forming a copper layer boss 3 based on the reserved region.

In some embodiments, by the adjustment of the operating parameters of the laser etching device, the single etching depth of the laser etching device can be adjusted, and it can be ensured that the laser etching device can completely etch and remove the superimposed copper layer.

Illustratively, in other embodiments, the superimposed copper layer may also be removed by grinding and polishing. The other regions outside the reserved region of the superimposed copper layer are ground by a grinding disc, and the ground superimposed copper layer is polished to maintain the smoothness of the top surface of the top copper layer 2, while it is ensured that the parts outside the reserved region of the superimposed copper layer are completely removed.

Illustratively, in other embodiments, the superimposed copper layer may also be etched and removed by chemical etching. A chemical etching agent is applied to the superimposed copper layer. When the chemical etching agent is applied, the position of the reserved region on the superimposed copper layer is avoided, and by the control of the dosage of the chemical etching agent applied each time, the etching rate and etching depth of the superimposed copper layer during each chemical etching are controlled. In this manner, precise etching of the superimposed copper layer is achieved, and a copper layer boss 3 is formed on the top copper layer 2 of the substrate.

In some embodiments, the chemical etching agent may be a strong oxidant. The superimposed copper layer is oxidized into copper ions by an oxidation reaction between the chemical etching agent and the superimposed copper layer, and the copper ions are combined with compounds in the chemical etching agent to prevent the copper ions from being deposited again. Thus, the copper ions can be removed by subsequent cleaning, thereby achieving the etching of the superimposed copper layer and preparing the copper layer boss 3.

Illustratively, after the copper layer boss 3 of the top copper layer 2 is processed and prepared, the top copper layer 2 is etched according to the circuit structure setting on the substrate, and several insulated channels 12 are formed on the top copper layer 2.

In some embodiments, the top copper layer 2 and the copper layer boss 3 are gold-plated to improve the welding reliability of the top copper layer 2 and facilitate the welding and encapsulation of other electronic components on the top copper layer 2.

Some embodiments of the present application also provide another method for preparing a substrate. In the preparation method, a mask with a slot is prepared, a copper layer is deposited in the slot to form a copper layer boss 3, and the installation height of the light-emitting element 6 in the light-emitting element installation region 13 is adjusted by the configuration of the copper layer boss 3. Thus, the light-emitting element 6 can meet the light-emitting requirements of the light-emitting module.

FIG. 6 is a flowchart of a method for preparing a substrate according to some embodiments of the present application. The preparation method includes the steps below.

In S21, a top copper layer 2 is formed on the top surface of a substrate body 1 using a copper coating process.

Illustratively, copper is coated on the substrate body 1 using the DBC process. Direct Bond Copper (DBC) is a ceramic surface metallization technology developed based on alumina ceramic substrates. By the attachment of copper foil to the substrate body 1, a top copper layer 2 is formed on the surface of the substrate body 1.

Illustratively, a copper foil with a preset thickness is provided, and the copper foil is placed in the air for pre-oxidation so that a certain thickness of copper oxide is formed on the surface of the copper foil.

Illustratively, a copper foil with a thickness of 0.1 mm or more is placed in the air for oxidation so that an oxide layer, that is, copper oxide, is generated on the surface of the copper foil. The thickness of the oxide layer accounts for about 20% of the thickness of the copper foil so that the copper foil contains a sufficient amount of oxygen atoms.

In some embodiments, the pre-oxidation operation of the copper foil may also include the following: by the placement of the copper foil in a nitrogen environment containing 1% oxygen for weak oxidation, a certain thickness of cuprous oxide is generated on the copper foil, thereby having a certain amount of oxygen atoms combined with the copper foil.

The pre-oxidized copper foil is attached to the top surface of the substrate body 1, and the copper foil is fixed to the substrate body 1 by high-temperature sintering.

Illustratively, the pre-oxidized copper foil is covered on the top surface of the substrate body 1, and the substrate body 1 and the copper foil are placed at a preset temperature and heated for a preset time so that a Cu—Cu₂O eutectic liquid is formed between the substrate body 1 and the copper foil, that is, a eutectic liquid of copper and cuprous oxide is formed. In this manner, the copper foil has good wettability to the substrate body 1, and the copper foil can be fixed on the substrate body 1 by generating a CuAlO₂ layer.

In some embodiments, the preset temperature is T, and the value range of T is as follows: 1065° C.≤T≤1083° C.; the preset time is t, and the value range of t is as follows: 10 min≤t≤15 min.

Illustratively, the copper foil and the substrate body 1 are cooled so that the copper foil is bonded and fixed to the substrate body 1, thereby preparing the top copper layer 2 on the top surface of the substrate body 1.

In some embodiments, the bottom copper layer 5 on the bottom surface of the substrate body 1 is formed based on the same process, and the top copper layer 2 and the bottom copper layer 5 may be simultaneously prepared, thereby improving the preparation and processing efficiency of the top copper layer 2 of the substrate body 1.

In S22, a mask with a preset slot is prepared on the top copper layer 2, where the preset slot corresponds to a light-emitting element installation region 13 of the top copper layer 2.

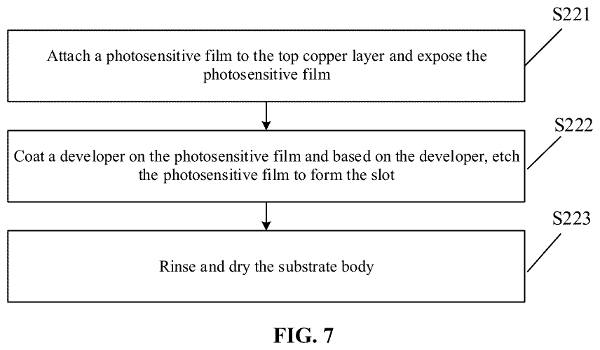

Illustratively, FIG. 7 is a flowchart of a method for preparing a mask according to some embodiments of the present application. Preparing the mask with the preset slot on the top copper layer 2 includes the steps below.

In S221, a photosensitive film is attached to the top copper layer 2, and the photosensitive film is exposed.

Illustratively, the photosensitive film is attached to the top copper layer 2, the position of a reserved region is marked on the photosensitive film according to the encapsulation size requirement of the substrate and the installation requirement of the light-emitting element 6, and by the adjustment of the light output size of the light-emitting element 6, the reserved region of the photosensitive film is exposed using a lighting device.

In some embodiments, a mask plate may be covered on the photosensitive film, and a notch matching the reserved region is opened on the mask plate so that the lighting device can accurately expose the reserved region.

In S222, a developer is coated on the photosensitive film, and based on the developer, the photosensitive film is etched to form the slot.

Illustratively, the developer is sprayed on the photosensitive film by rotary spraying. The developer is stored in a spraying device, and the nozzle of the spraying device is driven to rotate and spray the developer above the photosensitive film so that the developer evenly covers the surface of the photosensitive film, and the exposed part of the colloid on the photosensitive film can be rapidly dissolved in the developer. Thus, a slot is formed on the photosensitive film.

In some embodiments, photosensitive adhesive may be dissolved in the developer, and the dissolution rate of the photosensitive adhesive after exposure treatment in the developer is accelerated. The pattern etching operation of the photosensitive adhesive can be achieved by the difference in the dissolution rate between the exposed region and the non-exposed region of the photosensitive adhesive.

Illustratively, in some embodiments, the substrate body 1 may be placed in the developer so that the top copper layer 2 and the photosensitive film can be immersed in the developer, and the exposed part of the photosensitive film can be rapidly dissolved in the developer. Thus, a slot is formed on the photosensitive film.

In S223, the substrate body is rinsed and dried.

Illustratively, the substrate body 1 after exposure and development is rinsed with ultrapure water, the photosensitive adhesive and the developer on the substrate body 1 are rinsed clean, and the substrate body 1 is driven to rotate to perform a spin-drying operation, or the substrate body 1 is dried by air drying, thus forming a mask layer with a slot on the top copper layer 2.

In S23, copper ions are deposited on the slot to form a deposited copper layer, and a copper layer boss 3 is formed based on multiple depositions.

Illustratively, the thickness of the copper layer boss 3 is determined according to the encapsulation specification of the substrate. A photosensitive film with the same thickness as the copper layer boss 3 is selected to prepare a mask with a slot. A deposited copper layer is formed by deposition in the slot, and the deposited copper layer is completely filled in the slot, thereby obtaining the copper layer boss 3.

In some embodiments, when the thickness of the copper layer boss 3 is greater than the thickness of a single-layer sensing film, a first layer of the mask with a slot is prepared on the top copper layer 2, and a first layer of the deposited copper layer is deposited in the slot. By the repetition of S22 and S23, a second layer of the mask is prepared on the first layer of the mask, and a second layer of the deposited copper layer is formed on the first layer of the deposited copper layer until the thickness of the deposited copper layer meets the thickness requirement of the copper layer boss 3.

In S24, the mask is etched and removed to obtain a substrate with the copper layer boss 3.

Illustratively, the mask is exposed, and the exposed mask is soaked in a developer so that the mask can be completely dissolved in the developer, thereby etching and stripping the mask to obtain the substrate with the copper layer boss 3.

Illustratively, after the copper layer boss 3 of the top copper layer 2 is processed and prepared, the top copper layer 2 is etched according to the circuit structure setting on the substrate, and multiple insulated channels 12 are formed on the top copper layer 2. Thus, the top copper layer 2 forms a circuit structure based on the multiple insulated channels 12.

In some embodiments, the top copper layer 2 and the copper layer boss 3 are gold-plated to improve the welding reliability of the top copper layer 2 and facilitate the welding and encapsulation of electronic components on the top copper layer 2.

Some embodiments of the present application provide a method for preparing a substrate. In the preparation method, a mask with a slot is prepared, a copper layer is deposited in the slot to form a copper layer boss 3, and the installation height of the light-emitting element 6 in the light-emitting element installation region 13 is adjusted by the configuration of the copper layer boss 3. Thus, the light-emitting element 6 can meet the light-emitting requirements of the light-emitting module.

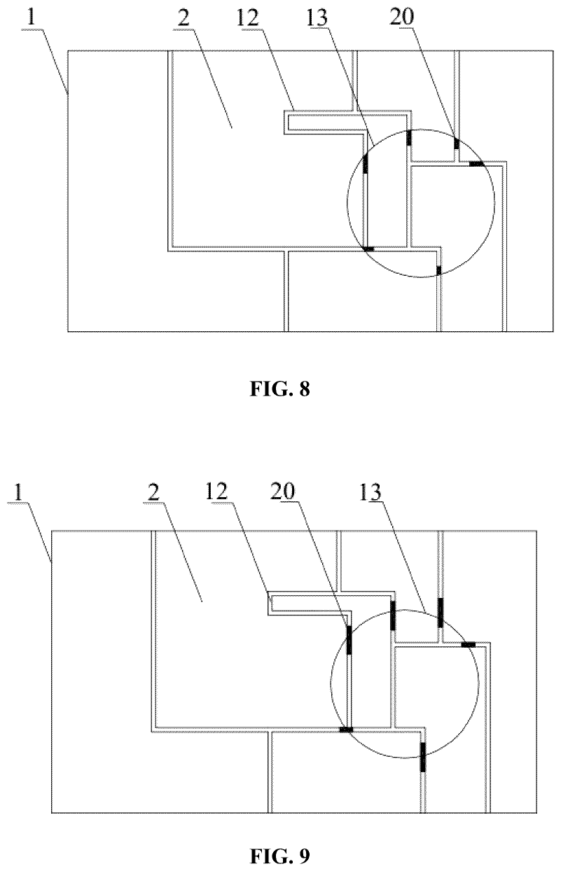

FIG. 8 is a diagram illustrating the structure of a substrate according to some embodiments of the present application. The structure of the substrate of these embodiments is basically the same as that of the substrate in preceding embodiments. The main difference is as follows: multiple barrier layers 20 are disposed in the multiple insulated channels 12, and the multiple barrier layers 20 are disposed at intersections between the contour line of the light-emitting element installation region 13 and the insulated channels 12; the multiple barrier layers 20 are used to isolate the light-emitting element installation region 13 on the substrate body 1 and the plastic encapsulation region on the substrate body 1 to prevent the plastic encapsulation adhesive from entering the light-emitting element installation region 13 through the insulated channels 12 in the plastic encapsulation process. It should be noted that the substrate of these embodiments may not include the copper layer boss 3.

In some embodiments, the top surface of the barrier layer 20 is flush with the top surface of the top copper layer 2, and the width of the barrier layer 20 is the same as the width of the insulated channel 12. That is, the barrier layer 20 is filled in the insulated channel 12, and the insulated channel 12 is cut off. When the light-emitting module is encapsulated, the light-emitting element installation region 13 is covered by a mold so that the mold can be tightly pressed on the top surface of the barrier layer 20 and the top copper layer 2 to avoid a gap between the mold and the barrier layer 20, thereby effectively preventing the plastic encapsulation adhesive from entering the light-emitting element installation region 13.

In some embodiments, during the plastic encapsulation, the light-emitting element installation region 13 is shielded by the mold, that is, the outer contour of the mold is the same as the contour of the light-emitting element installation region 13. According to actual processing requirements, the contour of the light-emitting element installation region 13 may be circular, elliptical, rectangular, or irregular.

Illustratively, in some embodiments, the barrier layer 20 is connected to the contour line of the light-emitting element installation region 13, and the barrier layer 20 is disposed in the light-emitting element installation region 13; one end surface of the barrier layer 20 is configured to be an arc surface, and the top arc of the arc surface is the same as the arc of the contour line of the light-emitting element installation region 13. During the plastic encapsulation, the outer contour of the mold overlaps the contour line of the light-emitting element installation region 13 so that misalignment and gaps between the barrier layer 20 and the mold are avoided. Moreover, one end surface of the barrier layer 20 can be flush with the outer wall of the mold to prevent the plastic encapsulation adhesive from entering the light-emitting element installation region 13 through the insulated channel 12.

Illustratively, the material of the barrier layer 20 may be ink. Ink is sprayed in a preset region in the insulated channel 12 by inkjet printing. Multiple layers of ink are formed in the preset region by layer-by-layer printing, and a barrier layer 20 is formed based on the multiple layers of ink.

In some embodiments, the barrier layer 20 may also be formed in the corresponding region of the insulated channel 12 by screen printing. The barrier layer 20 is covered on the top copper layer 2 of the substrate body 1 by a preset screen structure. Ink is applied on the screen structure, and the side surface is etched so that the ink layer is flush with the top surface of the top copper layer 2. Thus, the barrier layer 20 is obtained.

In some embodiments, the material of the barrier layer 20 may also be silicone. The barrier layer 20 is formed in a preset position of the insulated channel 12 by dripping glue. The material of the barrier layer 20 may also be epoxy resin. The epoxy resin locally encapsulates a corresponding region of the insulated channel 12 to obtain the barrier layer 20.

Illustratively, the barrier layer 20 may be a transparent barrier layer to prevent the barrier layer 20 from interfering with the light-emitting quality of the light-emitting element 6 in the light-emitting element installation region 13. The barrier layer 20 may also be a white barrier layer to reduce the influence of the barrier layer 20 on the light-emitting color of the light-emitting element 6.

In some embodiments, in the actual preparation process, the color of the barrier layer 20 is the same as the light-emitting color of the light-emitting element 6 in the light-emitting element installation region 13, thereby preventing the barrier layer 20 from affecting the light-emitting efficiency of the light-emitting element 6.

The present application provides a substrate. A barrier layer 20 is disposed at the intersection of the insulated channel 12 and the light-emitting element installation region 13 to effectively prevent the plastic encapsulation adhesive from entering the light-emitting element installation region 13 during plastic encapsulation. In this manner, the plastic encapsulation adhesive is prevented from affecting the light-emitting color of the light-emitting element 6, and the light-emitting quality of the light-emitting module is improved.

FIG. 9 is a diagram illustrating the structure of a substrate according to some embodiments of the present application. The structure of the substrate of these embodiments is basically the same as that of the substrate of previous embodiments. The main difference is as follows: the barrier layer 20 intersects with the contour line of the light-emitting element installation region 13, a portion of the barrier layer 20 is disposed in the light-emitting element installation region 13, and another portion of the barrier layer 20 is disposed outside of the light-emitting element installation region 13. During the plastic encapsulation, the mold is pressed onto the top surface of the barrier layer 20 so that misalignment and gaps between the barrier layer 20 and the mold are avoided. Moreover, one end surface of the barrier layer 20 can be flush with the outer wall of the mold to prevent the plastic encapsulation adhesive from entering the light-emitting element installation region 13 through the insulated channel 12.

A barrier layer 20 is disposed at the intersection of the insulated channel 12 and the light-emitting element installation region 13 to effectively prevent the plastic encapsulation adhesive from entering the light-emitting element installation region 13 during plastic encapsulation. In this manner, the plastic encapsulation adhesive is prevented from affecting the light-emitting color of the light-emitting element 6, and the light-emitting quality of the light-emitting module is improved.

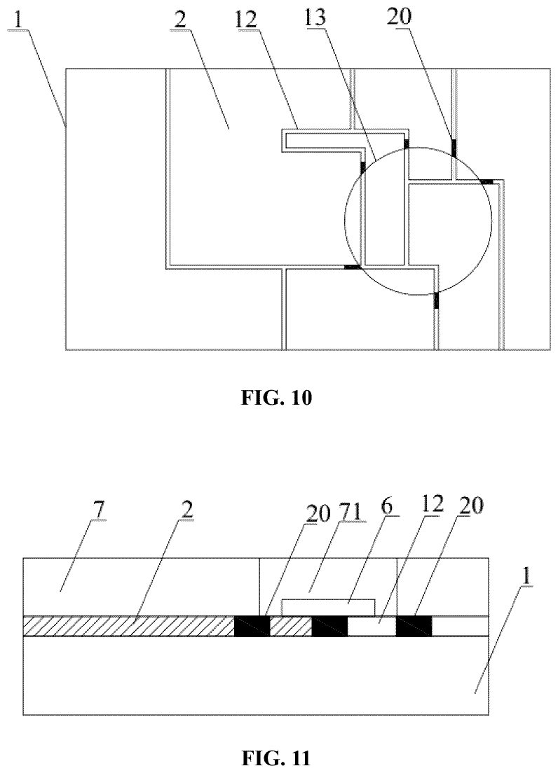

FIG. 10 is a diagram illustrating the structure of a substrate according to some embodiments of the present application. The structure of the substrate in these embodiments is basically the same as that of the substrate of previous embodiments. The main difference is as follows: the barrier layer 20 is connected to the contour line of the light-emitting element installation region 13, and the barrier layer 20 is disposed outside the light-emitting element installation region 13; one end surface of the barrier layer 20 is configured to be an arc surface, and the top arc of the arc surface is the same as the arc of the contour line of the light-emitting element installation region 13. During the plastic encapsulation, the outer contour of the mold overlaps the contour line of the light-emitting element installation region 13 so that misalignment and gaps between the barrier layer 20 and the mold are avoided. Moreover, one end surface of the barrier layer 20 can be flush with the outer wall of the mold to prevent the plastic encapsulation adhesive from entering the light-emitting element installation region 13 through the insulated channel 12.

A barrier layer 20 is disposed at the intersection of the insulated channel 12 and the light-emitting element installation region 13 to effectively prevent the plastic encapsulation adhesive from entering the light-emitting element installation region 13 during plastic encapsulation. In this manner, the plastic encapsulation adhesive is prevented from affecting the light-emitting color of the light-emitting element 6, and the light-emitting quality of the light-emitting module is improved.

In some embodiments, the thickness of the barrier layer 20 may be greater than the thickness of the top copper layer 2 so that multiple barrier layers 20 can be arranged in the circumferential direction at the outer edge of the contour line of the light-emitting element installation region 13. In this manner, the positioning of the mold can be achieved, and the reliability and accuracy of the plastic encapsulation are improved.

FIG. 11 is a sectional view illustrating the structure of a light-emitting module according to some embodiments of the present application. The light-emitting module includes a substrate, a light-emitting element 6 disposed on a top copper layer 2 of the substrate, and a plastic encapsulation layer 7 covered on the substrate. A light-emitting cavity channel 71 is disposed in the plastic encapsulation layer 7. The light-emitting element 6 is disposed in the light-emitting cavity channel 71. The light emission direction of the light-emitting element 6 is toward the cavity opening of the light-emitting cavity channel 71.

In some embodiments, a top copper layer 2 and a barrier layer 20 in an insulated channel 12 are disposed on the substrate body 1. The barrier layer 20 may isolate the plastic encapsulation layer 7 from the light-emitting element installation region 13 to prevent the plastic encapsulation layer 7 from affecting the light-emitting effect of the light-emitting element 6.

What is claimed is:

1. A substrate, comprising:
a substrate body; and
a top copper layer disposed on the substrate body, wherein a plurality of insulated channels are disposed on the top copper layer, the top copper layer forms a top circuit structure based on the plurality of insulated channels, and a light-emitting element installation region is disposed on the top layer circuit structure;
wherein the top copper layer in the light-emitting element installation region protrudes upward to form at least one copper layer boss;
a plurality of light-emitting element welding positions are disposed in the light-emitting element installation region;
a light-emitting element welding position of the plurality of light-emitting element welding positions is disposed on a copper layer boss of the at least one copper layer boss, and
the copper layer boss is configured to adjust a height of a light emission surface of a light-emitting element disposed in the light-emitting element installation region so that a height of a light emission surface of any light-emitting element disposed in the light-emitting element installation region is on a same horizontal plane.

2. The substrate of claim 1, wherein an area of a top surface of the copper layer boss is larger than an area of the light-emitting element welding position.

3. The substrate of claim 2, wherein a difference between a length of a contour edge of the top surface of the copper layer boss and a length of a contour edge of the light-emitting element welding position is d, and a value range of the length difference d is as follows: 4 μm≤d≤6 μm.

4. The substrate of claim 1, wherein a stepped structure is formed on a circumferential sidewall of the copper layer boss, or the circumferential sidewall of the copper layer boss is a smooth surface structure.

5. The substrate of claim 1, wherein the top copper layer and the at least one copper layer boss are an integrally formed structure.

6. The substrate of claim 1, wherein a plurality of barrier layers are disposed in the plurality of insulated channels, and the plurality of barrier layers are disposed at intersections between a contour line of the light-emitting element installation region and the plurality of insulated channels.

7. The substrate of claim 6, wherein at least one of the following configurations is satisfied: a top surface of a barrier layer of the plurality of barrier layers is flush with a top surface of the top copper layer; and
a width of a barrier layer of the plurality of barrier layers is the same as a width of an insulated channel of the plurality of insulated channels.

8. The substrate of claim 6, wherein a barrier layer of the plurality of barrier layers is connected to the contour line of the light-emitting element installation region, or a barrier layer of the plurality of barrier layers intersects with the contour line of the light-emitting element installation region.

9. The substrate of claim 8, wherein the barrier layer is connected to the contour line of the light-emitting element installation region, and one end surface of the barrier layer is an arc surface; and
a top arc of the arc surface of the one end surface of the barrier layer is the same as an arc of the contour line of the light-emitting element installation region.

10. A light-emitting module, comprising the substrate of claim 1, a plastic encapsulation layer disposed on the substrate, and a light-emitting element disposed in a light-emitting element installation region of the substrate;
wherein a light-emitting cavity channel is disposed in the plastic encapsulation layer, and the light-emitting element is disposed in the light-emitting cavity channel.

11. The light-emitting module of claim 10, wherein a top port of the light-emitting cavity channel is set as a light outlet; and
a distance between a light emission surface of the light-emitting element on the substrate and the light outlet is H1, a distance between a top surface of a top copper layer on the substrate and the light outlet is H2, a thickness of the light-emitting element is h1, and a thickness of a copper layer boss is h2, wherein a constraint relationship between H1, H2, h1, and h2 is as follows: h1+h2=H2−H1.

12. A preparation method for preparing a substrate, the preparation method is used to prepare the substrate of claim 1 and comprises:
forming a top copper layer on a top surface of a substrate body using a copper coating process;
performing deposition on the top copper layer to form a superimposed copper layer, and marking on the superimposed copper layer to form a reserved region; and
etching and removing the superimposed copper layer outside the reserved region on the superimposed copper layer to prepare a copper layer boss.

13. The preparation method of claim 12, wherein forming the top copper layer on the top surface of the substrate body using the copper coating process comprises:
coating copper on the substrate body using a direct bond copper (DBC) process, forming the top copper layer on the top surface of the substrate body, and forming a bottom copper layer on a bottom surface of the substrate body.

14. The preparation method of claim 12, wherein performing deposition on the top copper layer to form the superimposed copper layer and marking on the superimposed copper layer to form the reserved region comprises:
depositing copper metal on the top copper layer by metal sputtering so that the superimposed copper layer of a certain thickness is formed on a top surface of the top copper layer, and marking, by laser etching, on a surface of the superimposed copper layer to form the reserved region.

15. The preparation method of claim 12, wherein etching and removing the superimposed copper layer outside the reserved region on the superimposed copper layer to prepare the copper layer boss comprises:
setting a laser routing start point, a routing end point, and a routing path of a laser etching device, and etching and removing, by laser etching, the superimposed copper layer outside the reserved region on the superimposed copper layer.

16. A preparation method for preparing a substrate, the preparation method is used to prepare the substrate of claim 1 and comprises:
forming a top copper layer on a top surface of a substrate body using a copper coating process;
preparing a mask with a preset slot on the top copper layer, wherein the preset slot corresponds to a light-emitting element installation region of the top copper layer;
depositing copper ions on the slot to form a deposited copper layer, and forming a copper layer boss based on a plurality of depositions; and
etching and removing the mask to obtain a substrate with the copper layer boss.

17. The preparation method of claim 16, wherein preparing the mask with the preset slot on the top copper layer and the preset slot corresponding to the light-emitting element installation region of the top copper layer comprises:
attaching a photosensitive film to the top copper layer, and exposing the photosensitive film;
coating a developer on the photosensitive film, and etching, based on the developer, the photosensitive film to form the slot; and
rinsing and drying the substrate body.

18. The preparation method of claim 17, wherein attaching the photosensitive film to the top copper layer and exposing the photosensitive film comprises:
attaching the photosensitive film to the top copper layer;
marking a position of a reserved region on the photosensitive film according to an encapsulation size requirement of the substrate and an installation requirement of the light-emitting element; and
exposing the reserved region of the photosensitive film using a lighting device.

19. The preparation method of claim 17, wherein coating the developer on the photosensitive film and etching the photosensitive film based on the developer to form the slot comprises:
storing the developer in a spraying device; and
driving a nozzle of the spraying device to rotate and spray the developer above the photosensitive film so that the developer evenly covers a surface of the photosensitive film.

20. The preparation method of claim 16, wherein etching and removing the mask to obtain the substrate with the copper layer boss comprises:
exposing the mask; and
soaking the exposed mask in a developer so that the mask can be completely dissolved in the developer, thereby etching and stripping the mask to obtain the substrate with the copper layer boss.
